(19) United States
(12) Patent Application Publication
(10) Pub. No.: US 2025/0072177 A1
(43) Pub. Date: Feb. 27, 2025

(54) METHOD FOR MANUFACTURING SEMICONDUCTOR LIGHT EMITTING DEVICE

(71) Applicant: Stanley Electric Co., Ltd., Tokyo (JP)

(72) Inventor: Ji-Hao LIANG, Tokyo (JP)

(73) Assignee: Stanley Electric Co., Ltd., Tokyo (JP)

(21) Appl. No.: 18/810,540

(22) Filed: Aug. 21, 2024

(30) Foreign Application Priority Data
Aug. 23, 2023 (JP) 2023-135566

(51) Int. Cl. H01L 33/50; H01L 33/00; H01L 33/32

(52) U.S. Cl. CPC H01L 33/507; H01L 33/007; H01L 33/32; H01L 2933/0041

(57) ABSTRACT

A stacked body is formed by polishing an upper surface of a light emitting element plate, polishing a lower surface of a phosphor plate, mounting the phosphor plate on a light emitting element, and applying heat and applying pressure. From the phosphor plate side, incisions are inserted into the stacked body at positions corresponding to gaps between a plurality of semiconductor light emitting layers. From the light emitting element side, notches are formed in the stacked body at the gaps between the plurality of semiconductor light emitting layers. A semiconductor light emitting device is individualized by dividing the stacked body between a tip of the incision and a tip of the notch. One of the incision and the notch is formed with a depth extending beyond a bonding surface between the phosphor plate and the light emitting element plate.

### CROSS-REFERENCE TO RELATED APPLICATION

This application claims the benefit of and priority to Japanese Patent Application No. 2023-135566 filed on August 23 in 2023, and the content thereof is incorporated herein by reference in its entirety.

### BACKGROUND OF THE INVENTION

### 1. Field of the Invention

The present invention relates to a semiconductor light emitting device having a structure in which a semiconductor light emitting element and a phosphor plate are directly bonded without using a resin adhesive layer or the like.

### 2. Description of Related Art

JP2019-220675A and JP2021-197542A disclose methods for manufacturing a light emitting device in which a phosphor plate is directly bonded to a light emitting element by surface-activated bonding (SAB) without using an adhesive in a case of mounting the phosphor plate on the light emitting element. The light emitting devices manufactured by these manufacturing methods do not include an adhesive layer with a refractive index different from that of the light emitting element or the phosphor plate (especially, an adhesive layer with a refractive index lower than that of the light emitting element or the phosphor plate), so that a light extraction efficiency from the light emitting device is improved.

Specifically, in the manufacturing method of JP2019-220675A, the light emitting elements that have been individually divided in advance are arranged on a relay substrate, bonding surfaces of the light emitting elements and the phosphor ceramic are polished, and after that, these devices are placed in a vacuum device. In the vacuum device, each bonding surface is irradiated with an ion beam of a rare gas element (at least one of He, Ne, Ar, and Kr), and after that, the bonding surfaces are brought into contact with each other and pressurized to bond these bonding surfaces. After extracting the bonded light emitting elements and phosphor ceramics from the vacuum device, the phosphor ceramics are cut into individual light emitting devices by dicing to be individually divided.

On the other hand, JP2021-197542A discloses a method for manufacturing individual light emitting devices by directly bonding the substrate of the light emitting element to the phosphor plate by the surface-activated bonding, and after that, dividing both the light emitting element and the phosphor plate into the individual light emitting devices. In this manufacturing method, an element substrate on which a plurality of light emitting elements are formed and a phosphor plate are bonded by the surface-activated bonding. Before the bonding, the element substrate is thinned by grinding and polishing, and laser light irradiation is performed on boundary positions between elements of the thinned element substrate to form a crack. The phosphor plate is brought into contact with the element substrate with the crack formed therein, and pressurized to bond the phosphor plate to the element substrate by the surface-activated bonding. Then, the phosphor plate is cut with a blade to the middle of a thickness of the phosphor plate. The positions that are to be the boundaries between the elements are pressurized from the light emitting element side, the element substrate is divided by the crack, and simultaneously therewith, the semiconductor structure and wiring structure of the light emitting element where the crack is not provided as well as an uncut portion of the phosphor plate are also divided to be individualized.

### SUMMARY OF THE INVENTION

A manufacturing method of JP2019-220675A requires placing a light emitting element and a phosphor ceramic in a vacuum device to perform irradiation with an ion beam of a rare gas element to a bonding surface of the light emitting element and the phosphor ceramic for surface treatment. After irradiation with the ion beam, the bonding surfaces of the light emitting element and the phosphor ceramic are brought into contact and bonded in vacuum without opening the vacuum device to the atmosphere. As a result, all operations such as surface activation treatment, alignment, substrate heating, and substrate weighting need be performed in vacuum, which complicates the device configuration and makes the device expensive and which causes an increase in product costs.

In addition, in the manufacturing method of JP2019-220675A, the light emitting elements are individualized and arranged in advance, and the phosphor ceramics are surface-activated bonded to the individualized light emitting elements, and after that, the phosphor ceramics are cut into the individual light emitting devices to be individualized. This causes a problem that the size of the phosphor ceramic of the individualized light emitting device is necessarily larger than that of the light emitting element.

On the other hand, in the manufacturing method of JP2021-197542A, the light emitting elements are not individualized in advance, but cracks are introduced into the element substrate in advance by laser light so that the element substrate can be divided later, which causes reduction in strength of the element substrate. As a result, when the phosphor plate is brought into contact with the element substrate and pressure is applied to perform the surface-activated bonding, it is necessary to limit a load to be applied in order to prevent the element substrate from being cracked.

In addition, in the process after bonding the element substrate and the phosphor plate, the element substrate may be broken due to an internal stress, an external stress, or the like. When the element substrate is warped or is applied with an external force, the element substrate and the phosphor plate may be peeled off at the bonding surface.

Furthermore, in order to divide the element substrate and the phosphor plate after the bonding, the phosphor plate is cut halfway through a thickness of the phosphor plate, and cracks or incisions are not formed in the phosphor plate in the remaining thickness portion. Therefore, when the remaining thickness portion of the phosphor plate that has not been cut is pressurized for dividing, the portion may be broken at a position that is deviated from the crack position of the element substrate, or the portion may be broken by the crack spreading in a diagonal direction relative to the crack direction of the element substrate. When the phosphor plate is broken at the position that is deviated from the crack position or in the diagonal direction relative to the crack direction of the element substrate, a defective product with a disturbed side shape is made, which causes a decrease in yield of the finished product.

An object of the present invention is to improve a manufacturing yield in a method in which a phosphor plate and a light emitting element are bonded by surface-activated bonding and the phosphor plate and the light emitting element are divided to manufacture individual semiconductor light emitting layers.

In order to achieve the above object, a method for manufacturing a semiconductor light emitting device of the invention is a method for manufacturing a semiconductor light emitting device in which a phosphor plate absorbing light emitted from a semiconductor light emitting layer and emitting fluorescence is bonded to a light emitting element including the semiconductor light emitting layer, the method including:
a light emitting element t polishing process of polishing an upper surface of a light emitting element plate including a plurality of semiconductor light emitting layers arranged with gaps opened in a main plane direction;
a phosphor polishing process of polishing a lower surface of the phosphor plate;
a stacking process of mounting the phosphor plate on the light emitting element so that the upper surface of the light emitting element plate and the lower surface of the phosphor plate face each other, and applying heat and applying pressure to form a stacked body in which the phosphor plate is bonded to the light emitting element plate;
an incision forming process of forming incisions with a predetermined depth from the phosphor plate side of the stacked body at positions corresponding to the gaps between the plurality of semiconductor light emitting layers;
a notch forming process of forming notches in the gaps between the plurality of semiconductor light emitting layers from the light emitting element side of the stacked body; and
an individualizing process of dividing the stacked body between a tip of the incision and a tip of the notch to individualize the semiconductor light emitting devices.

A sum of the depth of the incision and a depth of the notch is shallower than a thickness of the stacked body, and one of the incision and the notch is formed with a depth extending beyond the bonding surface between the phosphor plate and the light emitting element plate.

With the semiconductor light emitting device of the invention, it is possible to improve a manufacturing yield of a method in which a phosphor plate and a light emitting element are bonded by the surface-activated bonding, and the phosphor plate and the light emitting element are divided to manufacture individual semiconductor light emitting layers.

### BRIEF DESCRIPTION OF THE DRAWINGS

FIGS. 1A and 1B are cross-sectional and top views of a semiconductor light emitting device according to a first embodiment;

FIGS. 2A to 2G are explanatory diagrams showing manufacturing processes of the semiconductor light emitting device according to the first embodiment;

FIGS. 3A to 3E are explanatory diagrams showing manufacturing processes of the semiconductor light emitting device according to the first embodiment;

FIG. 4 is a cross-sectional view showing a shape of a stacked body after the manufacturing process of FIG. 3C;

FIGS. 5A to 5E are diagrams showing examples of the cross-sectional shape of an incision 110 formed in the process of FIG. 3B of the first embodiment;

FIGS. 6A and 6B are cross-sectional and top views of a semiconductor light emitting device according to a modified example of the first embodiment;

FIG. 7 is a cross-sectional view of a semiconductor light emitting device according to a second embodiment;

FIGS. 8A to 8G are explanatory diagrams showing manufacturing processes of the semiconductor light emitting device according to the second embodiment; and

FIGS. 9A to 9E are explanatory diagrams showing manufacturing processes of the semiconductor light emitting device according to the second embodiment.

### DESCRIPTION OF EMBODIMENTS

Embodiments of the invention are described below.

### First Embodiment

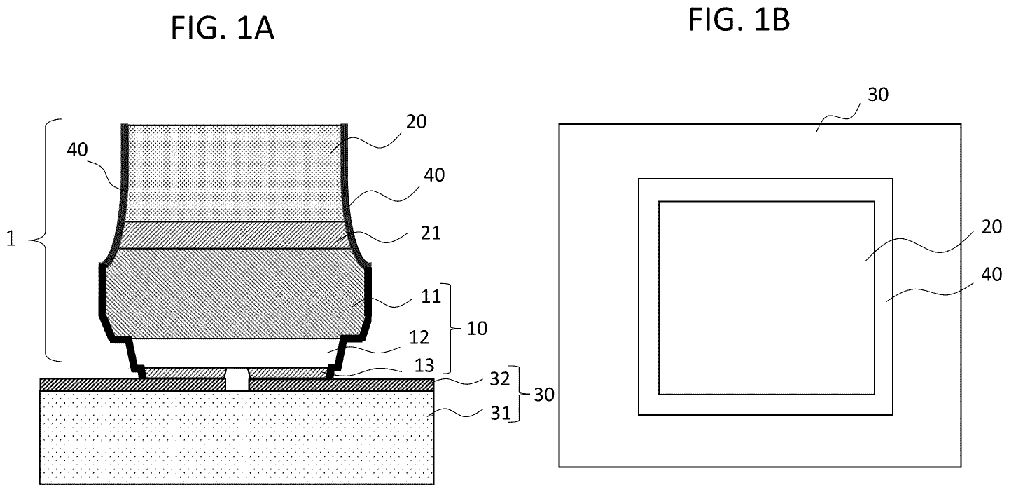

A method for manufacturing a semiconductor light emitting device according to a first embodiment is described with reference to FIGS. 1 to 4. FIGS. 1A and 1B are cross-sectional and top views of a semiconductor light emitting device 1 manufactured by the manufacturing method according to the first embodiment.

As shown in FIG. 1, in this embodiment, the semiconductor light emitting device 1 is manufactured by bonding a phosphor plate 20 to an upper surface of a light emitting element 10 by surface-activated bonding (SAB). In FIG. 1, the light emitting element 10 is a flip-chip type light emitting element and is configured to include a semiconductor light emitting layer 12, an element substrate 11 disposed on an upper surface of the semiconductor light emitting layer 12, and a pair of electrodes 13 disposed on a lower surface of the semiconductor light emitting layer 12. The phosphor plate 20 is bonded to an upper surface of the element substrate 11. A buffer layer 21 is disposed on a bonding surface between the element substrate 11 and the phosphor plate 20. In addition, side surfaces of the light emitting element 10, the buffer layer 21, and the phosphor plate 20 are formed partly by dicing and partly by cleavage, but have a smooth shape without any sharp angle and are covered with a light reflective multilayer film 40. It is noted that, the light reflective multilayer film 40 may not be provided. In addition, instead of forming the light reflective multilayer film 40, the side surfaces may be configured to be covered with a light reflective resin.

In the example of FIGS. 1A and 1B, the semiconductor light emitting device 1 is mounted on a substrate 31 having a pair of wirings 32, and the pair of electrodes 13 of the light emitting element 10 is electrically connected to the pair of wirings 32.

The phosphor plate 20 absorbs a part of the light emitted from the semiconductor light emitting layer 12 and emits fluorescence of a predetermined wavelength, thereby converting the wavelength of the light emitted from the semiconductor light emitting layer 12 and emitting the light from the upper surface.

The phosphor plate 20 is configured with, for example, a composite ceramic phosphor plate (Al₂O₃/Ce:YAG) in which Ce-doped YAG phosphor particles are dispersed in an alumina ceramic matrix. The element substrate 11 is configured with a material that transmits the light emitted by the semiconductor light emitting layer 12, for example, sapphire (Al₂O₃).

The surface-activated bonding is performed by bonding the materials on both sides of the bonding surface by intermolecular forces, and the distance between the molecules of the materials on both sides of the bonding surface needs to be set to a distance (up to 0.5 nm or less) at which intermolecular forces act. Therefore, in order to bond the phosphor plate 20 and the element substrate 11 by the surface-activated bonding, it is necessary to flatten the surfaces of the phosphor plate 20 and the element substrate 11 to a roughness equal to or less than the distance (up to 0.5 nm or less) at which intermolecular forces act.

The composite ceramic phosphor plate constituting the phosphor plate 20 is configured with microcrystalline particles, and the hardness of the microcrystalline particles of the ceramic matrix and the hardness of the microcrystalline particles of the phosphor are different from each other. The hardness of the microcrystalline particles also differs depending on the directions in which the crystal axes of the microcrystals are oriented in the phosphor plate 20. For this reason, even if the phosphor plate 20 is polished, a surface step difference (roughness) of about 1/20 of the particle size of the abrasive particles of the slurry used for polishing remains.

Specifically, for example, in the case of the phosphor plate 20 of the composite ceramic phosphor plate (Al₂O₃/Ce:YAG), when mirror polishing is performed with a slurry containing diamond particles of 1 μm as abrasive particles, a step difference of about 50 nm remains at the boundaries between the crystal particles due to the difference in hardness between Al₂O₃ and YAG. In addition, in a YAG-based Ce:YAG phosphor plate (a plate in which Ce-doped YAG phosphor particles are dispersed in a YAG ceramic matrix), the matrix and phosphor particles are ceramics of the same chemical formula, but due to the presence of microcrystalline particles, even when polished by a CMP (chemical mechanical polishing) method with a slurry containing diamond particles with a particle size of 50 nm as abrasive particles, a surface step difference of about +2 nm (roughness Ra is up to 1.5 nm) For this reason, it is difficult to flatten the surface of the phosphor plate 20 to a roughness equal to or less than the distance (up to 0.5 nm or less) at which intermolecular forces act.

In this embodiment, a buffer layer 18 is formed on the surface of the phosphor plate 20, and the buffer layer 18 is flattened to a roughness equal to or less than the distance (up to 0.5 nm or less) at which intermolecular forces act. For CMP polishing of the buffer layer 18, a nano-slurry (diamond, silica, or alumina) with a particle size of several nm to several tens of nm is used. For example, the phosphor plate 20 is polished by CMP (chemical mechanical polishing) method using a slurry containing diamond particles with a particle size of 50 nm as abrasive particles. If necessary, the polished surface is further polished (finely scraped), organic contaminants on the surface are removed, and in order to activate a bonding surface (the bonds of the surface molecules are broken to form dangling bonds), ultraviolet light (for example, excimer light) treatment and plasma treatment are performed, and after that, the buffer layer 21 is formed by vapor phase growth. Immediately after the film forming, the surface of the buffer layer 21 has an uneven shape that follows the unevenness of the polished surface of the phosphor plate 20, but by CMP polishing the buffer layer 21, it is possible to flatten the surface of the buffer layer to a roughness equal to or less than the distance (up to 0.5 nm or less) at which intermolecular forces act.

It is preferable that a layer made of an amorphous dielectric material is formed as the buffer layer 21. By making the buffer layer 21 amorphous, the flatness after the CMP polishing can be improved compared to the case where the buffer layer contains microcrystals. The buffer layer 21 is preferably, for example, an amorphous Al₂O₃ thin film (for example, the thickness is about 200 nm to 1000 nm) formed by EB (electron beam) deposition. The CMP polishing of the buffer layer 21 is performed, for example, by using a surface plate equipped with a buff with a relatively low hardness and a silica-based slurry.

The buffer layer 21 is not limited to the amorphous Al₂O₃ thin film and may be any inorganic material that is transparent to the light emitted by the semiconductor light emitting layer 12 (for example, has no light absorption over the entire white spectrum), has a thermal expansion coefficient and an optical refractive index close to those of the element substrate 11 and the phosphor plate 20, has excellent thermal conductivity, is highly resistant to acids and alkalis, and has low stress corrosion resistance, and can be flattened to a roughness equal to or less than the distance (up to 0.5 nm or less) at which intermolecular forces act.

For example, dielectric materials such as oxides containing Al (for example, Al₂O₃), SiO₂, Nb₂O₅, Ta₂O₅, TiO₂, Y₂O₃, MgO, and ZrO₂ can be preferably used as the material for the buffer layer 21.

In addition, in order to flatten the buffer layer 21 to a roughness equal to or less than the distance (up to 0.5 nm or less) at which intermolecular forces act, the buffer layer 21 is preferably amorphous, and in particular, the buffer layer 21 is preferably amorphous and does not contain microcrystals. In addition, in the case where the buffer layer 21 contains microcrystals, it is preferable that the size of the microcrystalline particles is 50 nm or less, and particularly 10 nm or less.

In addition, by using the amorphous buffer layer 21, the hardness is lower than the case where the buffer layer 21 made of a single crystal is used, and the buffer layer 21 has flexibility when the phosphor plate 20 provided with the buffer layer 21 is brought into contact with the element substrate 11. Therefore, by applying pressure, the buffer layer 21 is plastically deformed and can be closely adhered to the surface shape of the element substrate 11, so that the surface-activated bonding can be easily performed.

It is preferable that the buffer layer 21 does not contain cavities (voids). When the voids are included, a surface flatness of the buffer layer 21 is deteriorated, which will be a factor in reducing a bonding strength of the surface-activated bonding.

The method of forming the buffer layer 21 is not limited to an EB deposition method, and other film forming methods such as sputtering, CVD (chemical vapor deposition), and ALD (atomic layer deposition) can be used. The buffer layer 21 can be configured as an amorphous buffer layer by adjusting the film forming conditions such as a film forming temperature.

The thickness of the buffer layer 21 may be any thickness that can be flattened to a roughness equal to or less than a distance (up to 0.5 nm or less) at which intermolecular forces act, and for example, the thickness is preferably 50 nm to 2 μm, and particularly preferably about 200 nm to 600 nm.

In addition, the phosphor plate 20 is not limited to a composite ceramic phosphor plate (Al₂O₃/Ce:YAG), and may be a phosphor plate made of a Ce:YAG single crystal, a phosphor ceramic plate with a YAG base (YAG/Ce:YAG), or glass. In addition, in the composite ceramic phosphor plate, the particle size and density of the YAG particles can be appropriately selected according to the application.

The light emitting element 10 can be, for example, a blue LED in which the element substrate 11 is any one of a sapphire substrate, a spinel substrate, and a GaN substrate and the semiconductor light emitting layer 12 includes a GaN layer.

It is preferable that the buffer layer 21 is provided on the phosphor plate 20 side in the manufacturing process, but the buffer layer may be provided on both the phosphor plate 20 and the element substrate 11. In addition, the buffer layer 21 may be provided only on the element substrate 11.

In addition, in the present embodiment, during the manufacturing of the semiconductor light emitting device 1, a large phosphor plate 20 in which the phosphor plates 20 of the plurality of semiconductor light emitting devices 1 are continuous is bonded to a large element substrate 11 having a configuration in which the plurality of light emitting elements 10 are continuous to form the stacked body. Then, in order to divide the stacked body at the boundary positions of the plurality of semiconductor light emitting devices 1 to obtain individual semiconductor light emitting devices 1, incisions are inserted from the phosphor plate 20 side of the stacked body by dicing or the like, and notches are formed from the semiconductor light emitting layer 12 side of the element substrate 11. At this time, the incisions are formed so as to penetrate the buffer layer 21. Specifically, the incisions are formed so as to penetrate the buffer layer 21 and reach the element substrate 11. That is, the incisions are formed so as to penetrate the bonding surface between the phosphor plate 20 and a light emitting element plate 100 and reach the light emitting element plate 100 (the element substrate 11 in this case). This releases the internal stress at the bonding surface between the phosphor plate 20 and the element substrate 11 and prevents stress concentration at the bonding surface when an external force is applied, and the element substrate 11 and the phosphor plate are prevented from peeling off at the bonding surface. This improves the manufacturing yield. This will be described in detail below in the description of the manufacturing method.

### <Manufacturing Method>

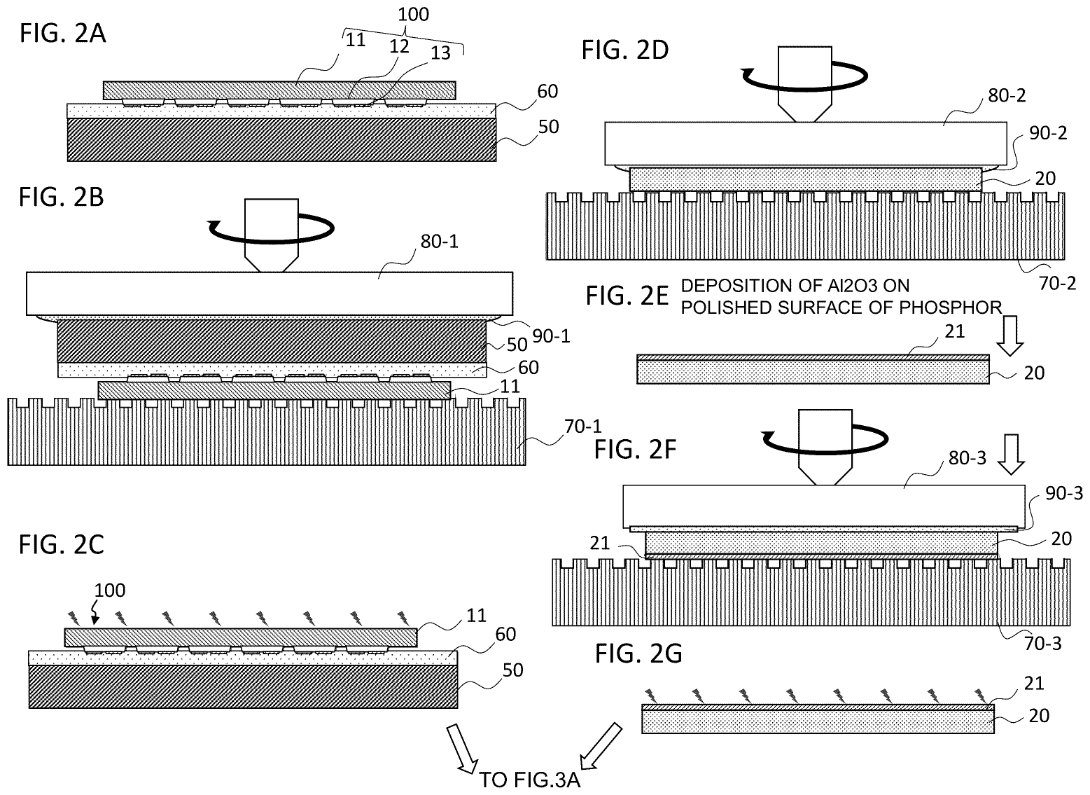

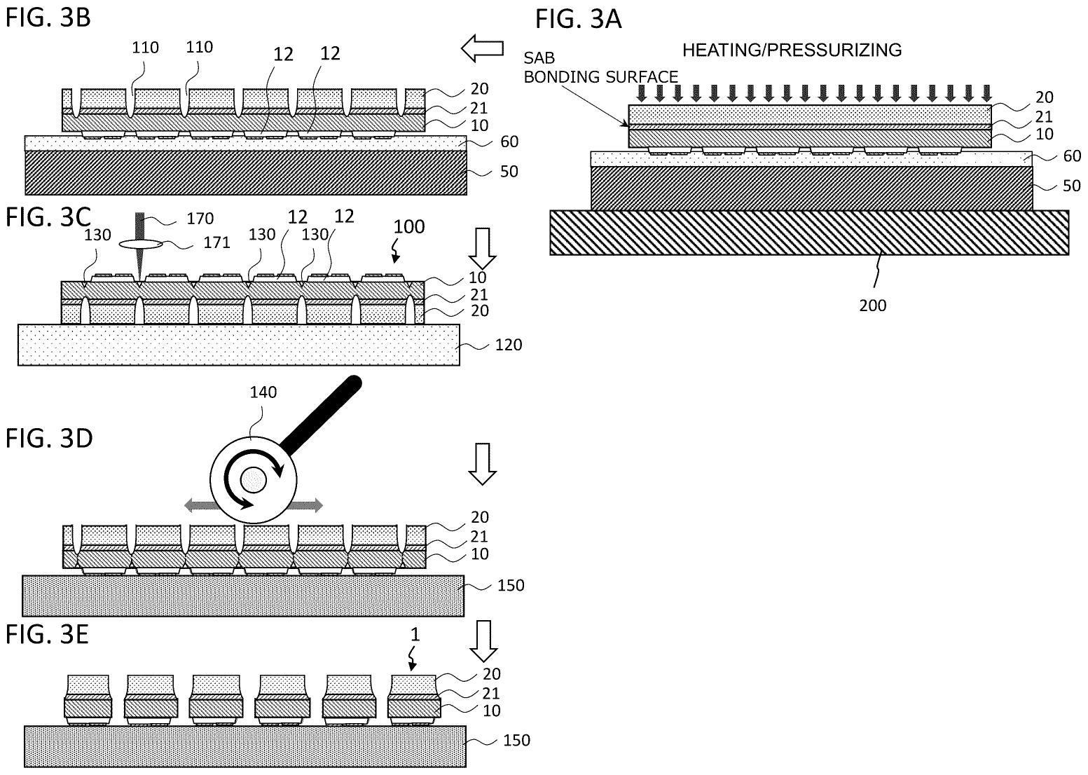

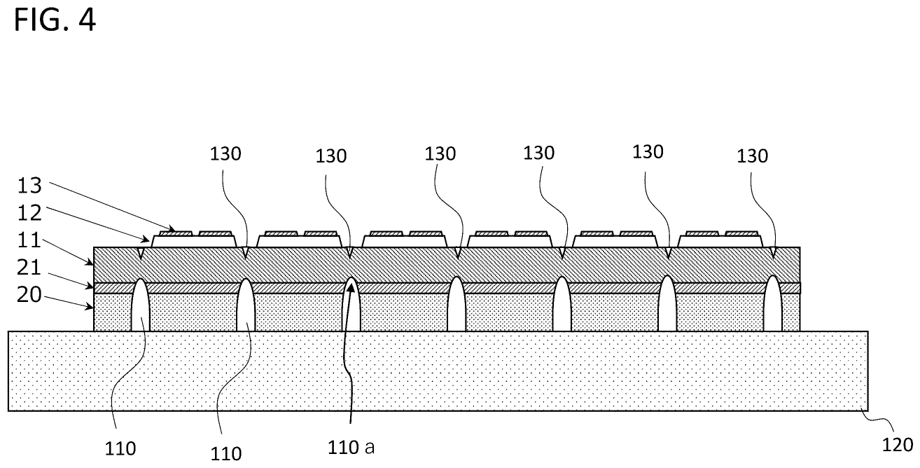

FIGS. 2 and 3 are diagrams illustrating the manufacturing processes of this manufacturing method. FIG. 4 is a cross-sectional view showing the shape of the stacked body after the manufacturing process of FIG. 3C.

The manufacturing process will be described by using FIGS. 2 to 4.

### (Polishing Process of Light Emitting Element 10)

First, as shown in FIG. 2A, the light emitting element plate 100 is prepared in which a plurality of semiconductor light emitting layers 12 and electrodes 13 are arranged to be arrayed on the lower surface of a continuous element substrate 11 with gaps opened in a main plane direction. The gaps between the plurality of semiconductor light emitting layers 12 of the light emitting element plate 100 are designed so that individual light emitting elements 10 can be obtained by dividing the element substrate 11 at the boundaries between the adjacent light emitting elements 10.

As shown in FIG. 2A, a support substrate 50 is bonded to a plurality of the arrayed semiconductor light emitting layers 12 of the light emitting element plate 100 by a heat-resistant adhesive layer 60.

As shown in FIG. 2B, the back side (the surface opposite to the side to which the semiconductor light emitting layers 12 are bonded) of the support substrate 50 is fixed to a polishing stage 80-1 by an adhesive layer 90-1.

A polishing surface plate 70-1 is prepared, and the back side of the element substrate 11 of the light emitting element plate 100 is cut and polished by the polishing surface plate 70-1 by using a slurry containing diamond abrasive particles to make the back side thinner, and the surface of the element substrate 11 is flattened to a roughness (Ra) equal to or less than the distance (up to 0.5 nm or less) at which intermolecular forces act.

Specifically, for example, a grinding process, a mechanical polishing process, and a CMP polishing process are performed in sequence by using the polishing surface plate 70-1.

For example, in the grinding process, a grinding machine is used to thin the thickness (for example, 830 μm) of the element substrate 11 to 150 μm using a grinding wheel with a particle size of #230. The roughness (Ra) of the element substrate 11 after the grinding is about 200 nm.

Next, in the mechanical polishing process, by performing first mechanical polishing of the surface of the element substrate 11 with a thickness of 150 μm after the grinding process by using a slurry containing diamond abrasive particles with a particle size of 6 μm, the roughness (Ra) of the element substrate 11 is made to be less than 50 nm. This first mechanical polishing process can remove scratches and crack layers on the surface that occurred in the grinding process. The thickness of the element substrate after this first mechanical polishing process is about 120 μm. After that, by performing second mechanical polishing by using a slurry containing diamond abrasive particles with a particle size of 1 μm, the roughness (Ra) of the element substrate 11 is made to be less than 10 nm.

Next, in the CMP polishing process, CMP polishing is performed by using a slurry containing diamond abrasive particles with a particle size of 50 nm, and the roughness (Ra) of the element substrate 11 is reduced to less than 0.5 nm.

By these processes, the surface of the element substrate 11 can be flattened to a roughness (Ra) of less than 0.5 nm, which is less than the distance (up to 0.5 nm or less) at which intermolecular forces act.

Next, as shown in FIG. 2C, the surface of the element substrate 11 after the polishing is treated with ultraviolet light (excimer light) and treated with a plasma.

Specifically, the polished surface of the element substrate 11 is irradiated with ultraviolet light (excimer light: wavelength (175±15) nm) and cleaned.

Then, the light emitting element plate 100 is placed in the vacuum device, and a plasma of one or a mixture of two or more of Ar, O₂, and N₂ is generated with high-frequency power (100 W to 450 W, preferably 250 W to 350 W), and the polished surface of the element substrate 11 is plasma-treated for a predetermined treatment time (1 min to 10 min, preferably 3 min to 6 min).

### (Polishing Process of Phosphor Plate 20)

Meanwhile, as shown in FIG. 2D, the phosphor plate 20 with a size corresponding to the continuous phosphor plates 20 of the plurality of semiconductor light emitting devices 1 is prepared, and fixed to a polishing stage 80-2 by an adhesive layer 90-2.

A polishing surface plate 70-2 is prepared, and the surface of the phosphor plate 20 is polished by the polishing surface plate 70-2 by using a slurry containing diamond abrasive particles.

Specifically, for example, a mechanical polishing process is performed, and then a CMP polishing process is performed by using the polishing surface plate 70-2.

In the mechanical polishing process, the surface of the phosphor plate 20 is mechanically polished by using a slurry containing diamond abrasive particles with a particle size of 6 μm, and after that, by further performing the mechanical polishing by using a slurry containing diamond abrasive particles with a particle size of 1 μm, so that the roughness (Ra) of the element substrate 11 is made to be less than 10 nm.

Next, in the CMP polishing process, CMP polishing is performed by using a slurry containing diamond abrasive particles with a particle size of 50 nm, and the roughness (Ra) of the phosphor plate is reduced to less than 1 nm. It is noted that the CMP polishing process is performed as necessary.

After that, the polishing stage 80-2 is removed from the phosphor plate 20.

### (Film Forming and Polishing of Buffer Layer 21)

Next, as shown in FIG. 2E, the buffer layer 21 is formed on the polished surface of the phosphor plate 20.

For example, an amorphous Al₂O₃ film is formed with a thickness of 600 nm by the EB deposition.

As shown in FIG. 2F, the surface of the phosphor plate 20 opposite to the surface on which the buffer layer 21 is formed is fixed to a polishing stage 80-3 by an adhesive layer 90-3.

A polishing surface plate 70-3 is prepared, and the surface of the buffer layer 21 of the phosphor plate 20 is CMP-polished by the polishing surface plate 70-3 by using a slurry containing silica particles of several nm to several tens of nm, so that a roughness Ra is made to be less than 0.5 nm. This roughness is a roughness Ra equal to or less than the distance (up to 0.5 nm or less) at which intermolecular forces act.

Next, as shown in FIG. 2G, the surface of the phosphor plate 20 after the polishing is treated with ultraviolet light (excimer light) and treated with a plasma. The conditions for these treatments are the same as those in FIG. 2C, and thus, a description thereof will be omitted.

It is preferable that the ultraviolet light (excimer light) treatment and plasma treatment of the element substrate 11 in FIG. 2C and the ultraviolet light (excimer light) treatment and plasma treatment of the phosphor plate 20 in FIG. 2G are completed simultaneously.

After the plasma treatment, the light emitting element 10 and the phosphor plate 20 are extracted from the vacuum device.

### (Bonding Process)

Next, as shown in FIG. 3A, the light emitting element plate 100 supported by the support substrate 50 is mounted on a heating/pressurizing table 200, and the phosphor plate 20 is mounted on top of the light emitting element plate. At this time, the plates are mounted so that the surface of the light emitting element plate 100 where the polishing of the element substrate 11, the treatment with ultraviolet light (excimer light), and the plasma treatment have been performed comes into contact with the surface of the buffer layer 21 where the polishing of the phosphor plate 20, the treatment with ultraviolet light (excimer light), and the plasma treatment have been performed.

The light emitting element plate 100 and the phosphor plate 20 are heated to 100° C. to 300° C., preferably 150° C. to 250° C., by the heating/pressurizing table 200 under normal pressure in the state shown in FIG. 3A, a load (for example, 2 MPa or more, preferably 10 MPa or more) is applied to the light emitting element plate 100 and the phosphor plate 20, the heated and pressurized state is maintained for 30 minutes or more, preferably 2 hours or more, and the light emitting element plate 100 and the phosphor plate 20 are bonded by the surface-activated bonding. Accordingly, the element substrate 11 and the phosphor plate 20 are bonded via the buffer layer 21 by the surface-activated bonding, and the stacked body is formed.

The light emitting element plate 100 and the phosphor plate 20 may be placed in the vacuum device and bonded by applying heat and applying pressure under reduced pressure.

### (Incision Forming Process)

As shown in FIG. 3B, the groove-shaped incisions 110 with a predetermined depth are inserted from the phosphor plate 20 side of the stacked body at positions corresponding to the gaps between the plurality of semiconductor light emitting layers.

The incisions 110 reach the buffer layer 21 and penetrate the buffer layer 21. The incisions 110 penetrate the bonding surface between the phosphor plate 20 and the light emitting element plate 100 to reach the element substrate 11.

Specifically, the incisions 110 are formed by blade dicing using a blade with a blade width of, for example, 20 μm to 500 μm. The incisions 110 are formed so that the incisions penetrate the phosphor plate 20 and the buffer layer 21 to invade the element substrate 11 to a depth of 1 μm to 50 μm, preferably 1 μm to 20 μm.

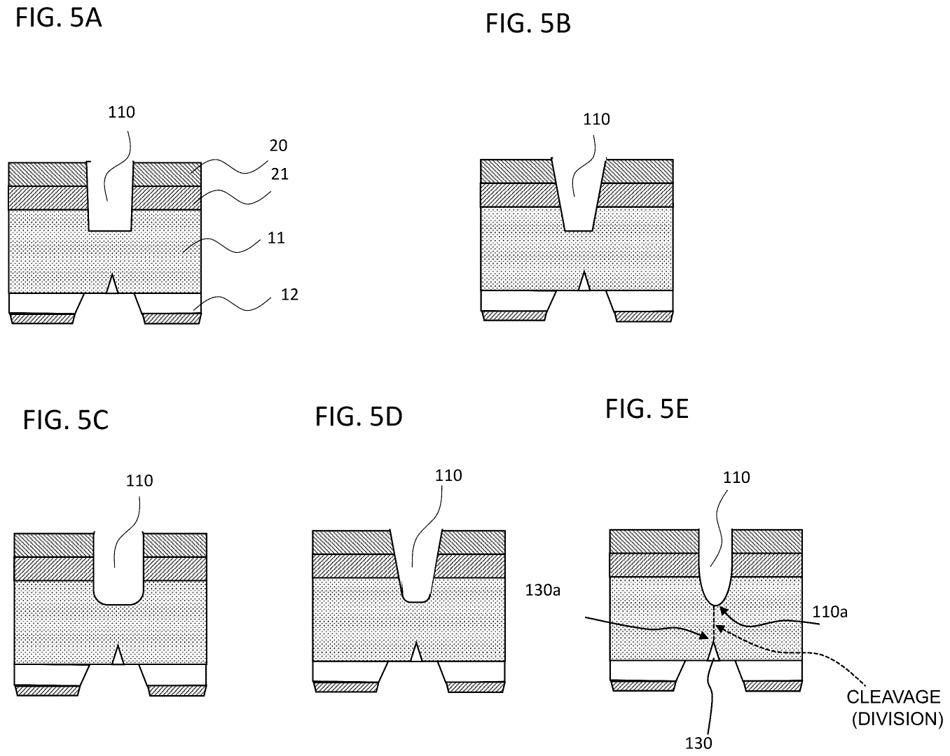

The cross-sectional shape of the incision 110 may be any of a rectangle (FIG. 5A), a trapezoid (FIG. 5B), a rectangle with rounded corners (FIG. 5C), a trapezoid with rounded corners (FIG. 5D), and a parabolic shape (FIG. 5E), as shown in FIG. 5A to 5E. However, a shape with rounded corners (FIG. 5C to 5E) is preferable, and a parabolic shape (FIG. 5E) is particularly preferable.

The incision 110 with a parabolic cross section (FIG. 5E) has a shape in which the incision 110 is closest to a lower surface of the element substrate 11 (a surface on which the semiconductor light emitting layer 12 is mounted) at one point of a tip 110a of the incision cross section. Therefore, in the individualizing process described later, by applying a force to the stacked body, stress is concentrated at the one point of the tip 110a, and the element substrate 11 can be divided by cleavage or the like starting from this position.

Herein, the incisions 110 are formed by blade dicing, but the incisions can also be formed by laser dicing.

### (Notch Forming Process)

Next, as shown in FIG. 3C, the support substrate 50 is removed from the semiconductor light emitting layers 12, and an adhesive sheet 120 is adhered to the phosphor plate 20 side of the stacked body.

From the light emitting element plate 100 side of the stacked body, groove-shaped notches 130 are formed in the element substrate 11 at the gaps between the plurality of semiconductor light emitting layers 12.

Specifically, for example, a laser scribing device focuses laser light 170 with a lens 171 and irradiates the element substrate 11 at the gaps between the plurality of semiconductor light emitting layers 12 with the focused laser light to form the groove-shaped notches 130.

A sum of the depth of the notch 130 and the depth of the incision 110 is set to be shallower than the thickness of the stacked body. The stacked body is divided by cracks such as cleavage.

It is noted that a protective film may be formed by a coating method on the surface of the semiconductor light emitting layer before forming the notches 130 by using the laser scribing device. The protective film prevents contaminants generated by laser scribing from adhering to the surface of the semiconductor light emitting layer. The protective film can be removed by washing with water in a later process.

It is preferable to use a nano-pulse or pico-pulse laser as the laser light 170. The wavelength of the laser light 170 used can be 355 nm.

The shape of the notch 130 is preferably a wedge shape, and the width of the notch 130 is preferably 10 μm or less, and particularly preferably 2 μm or less. The depth of the notch 130 is preferably 2 μm or more, and particularly preferably 5 μm or more.

As a result, the stacked body has the shape shown in FIG. 4.

After forming the notches 130, the stacked body is subjected to washing with water and organic cleaning to remove contaminants caused by the laser scribing.

In FIG. 3C, the irradiation with the laser light 170 is performed from the semiconductor light emitting layer 12 side, but it is also possible to perform irradiation with the laser light 170 from the phosphor plate 20 side to form the notches 130 at the positions of the notches 130 in the element substrate 11 in FIG. 3C. For example, in a stealth dicing device, a divided surface can be formed in the element substrate 11.

In addition, since the gaps between the semiconductor light emitting layers 12 are narrow here, the notches 130 are formed by the laser scribing, but it is also possible to provide the notches 130 by a blade dicing using a thin blade.

### (Individualizing Process)

As shown in FIG. 3D, the surface of the light emitting element 10 of the stacked body is placed downward and adhered to an adhesive sheet 150.

When a roller 140 is used to lightly press the entire surface of the phosphor plate 20 of the stacked body, the element substrate 11 between the tip 110a of the incision 110 and a tip 130a of the notch 130 (refer to FIG. 5E) is divided and broken (refer to FIG. 5E). As a result, the semiconductor light emitting device 1 is individualized.

It is noted that, since the thermal expansion coefficient of the phosphor plate 20 is larger than that of the element substrate 11, if the conditions are appropriately set when performing irradiation with the laser light 170 to form the notch 130 in the process of FIG. 3C. Therefore, it is possible to individualize the element substrate 11 between the notch 130 and the incision 110 by cleavage or the like by simply performing irradiation with the laser light 170 to form the notch 130. In this case, the process of applying a force by the roller 140 can be omitted.

### (Process of Opening Gaps of Semiconductor Light Emitting Devices 1)

Finally, the adhesive sheet 150 is stretched in the main plane direction (expanding is performed) to widen the gaps between the semiconductor light emitting devices 1 on the adhesive sheet 150. This makes the semiconductor light emitting devices 1 ready for handling.

As described above, the semiconductor light emitting devices 1 can be manufactured (refer to FIG. 1)

In addition, as described above, in this embodiment, the buffer layer 21 is provided and polished, so that the phosphor plate 20 can be bonded to the light emitting device by the surface-activated bonding without being affected by the crystal particles of the phosphor plate 20.

In addition, the incisions 110 are provided to a depth reaching the buffer layer 21 in the stacked body in which the element substrate 11 of the light emitting element plate 100 and the phosphor plate are surface-activated bonded, so that the element substrate 11 and the phosphor plate can be prevented from being peeled off at the bonding surface due to internal stress at the bonding surface or external force. Furthermore, in the dicing for forming the incisions 110, since substantially no substrate dicing is performed after penetrating the bonding surface (about 5 μm to 20 μm), a narrow dicing blade can be used. As a result, the width of the incisions 110 provided between the light emitting elements can be formed to be small.

In addition, by providing the notch 130 between adjacent semiconductor light emitting layers, the element substrate between the notch 130 and the incision 110 can be accurately and easily divided by cleavage or the like at the position connecting the notch 130 and the incision 110. Therefore, the phosphor plate and the element substrate can be accurately divided and individualized into individual semiconductor light emitting devices 1, so that the manufacturing yield is improved.

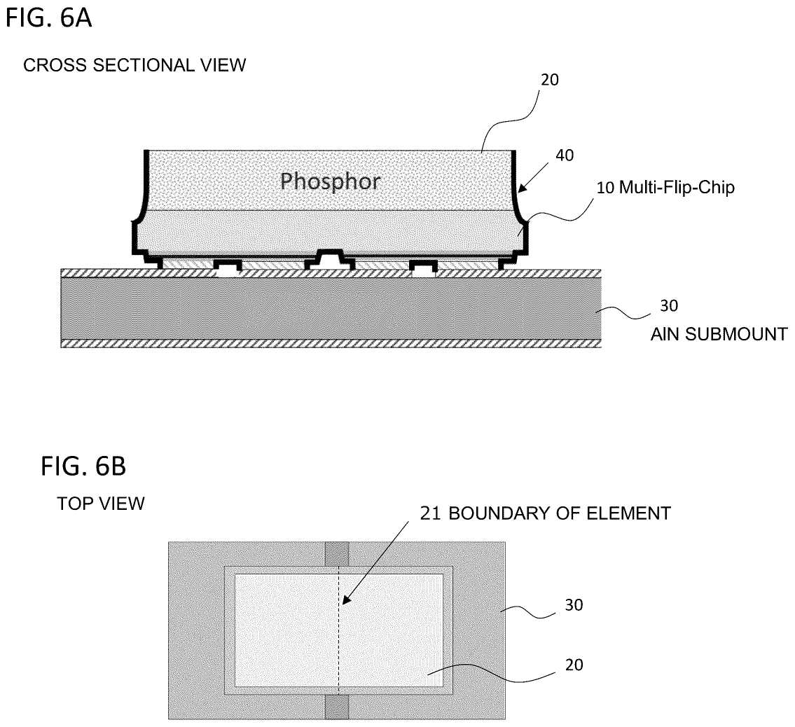

It is noted that, in this embodiment, a semiconductor light emitting device having the pair of electrodes 13 was manufactured as shown in FIG. 1, but a structure having two pairs of electrodes 13 in one semiconductor light emitting device as shown in FIGS. 6a and 6b can also be manufactured by the manufacturing processes described above.

### Second Embodiment

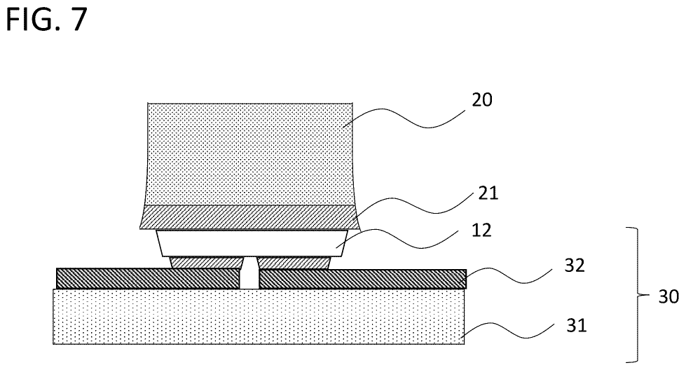

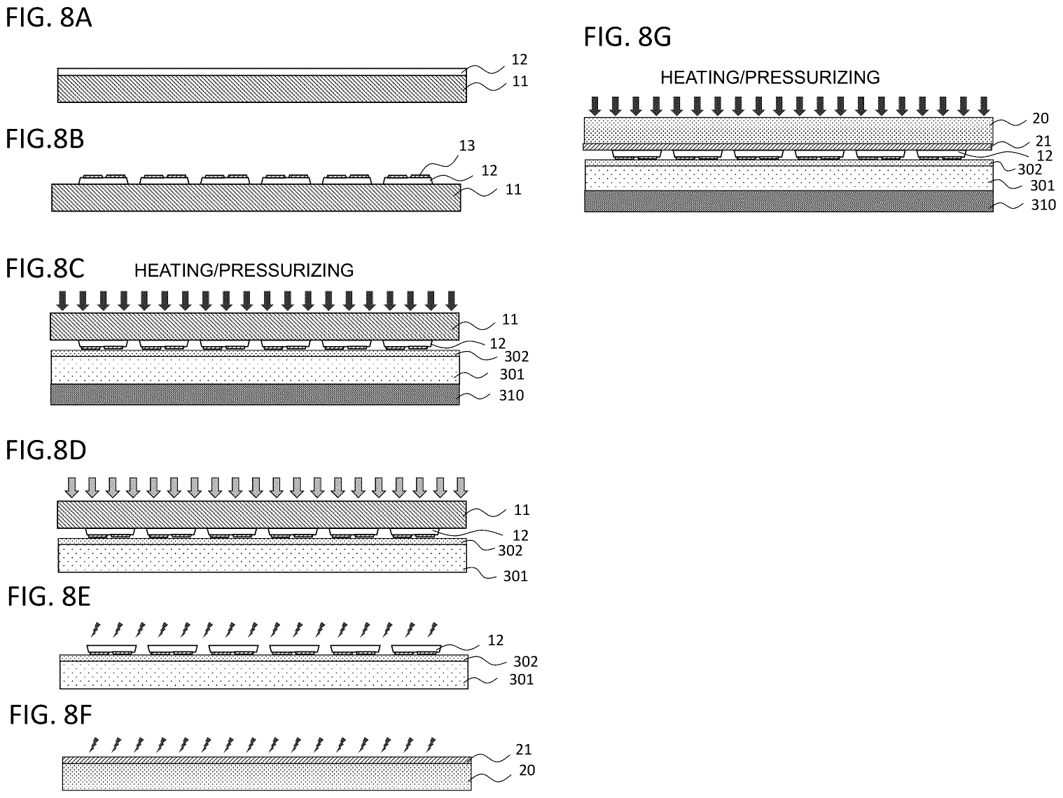

In a second embodiment, a semiconductor light emitting device not including an element substrate 11 is manufactured as shown in FIG. 7. The manufacturing method will be described with reference to FIG. 8. In FIG. 8, the same manufacturing method as in FIG. 2 and FIG. 3 will not be described.

As shown in FIG. 8A, a light emitting element plate 100 is prepared in which a semiconductor light emitting layer 12 is formed on the front surface of the element substrate 11.

As shown in FIG. 8B, the semiconductor light emitting layer 12 is processed by etching or the like into the shape of the semiconductor light emitting layer 12 for each semiconductor light emitting device. After that, a pair of electrodes 13 is formed on each semiconductor light emitting layer 12.

As shown in FIG. 8C, the electrodes 13 of the semiconductor light emitting layers 12 are fixed to a translucent support substrate 301 by an adhesive layer 302 made of a resin adhesive. The support substrate 301 is mounted on a support stand 310.

As shown in FIG. 8D, the element substrate (sapphire substrate) 11 is irradiated with laser light such as an excimer laser, and the element substrate 11 is removed by laser lift-off. Accordingly, the semiconductor light emitting layers 12 are exposed, as shown in FIG. 8E.

In FIG. 8E, the exposed semiconductor light emitting layers 12 are polished to flatten the surfaces, and are then treated with ultraviolet light (excimer light) and treated with a plasma. The polishing, the ultraviolet light (excimer light) treatment, and the plasma treatments are performed in the same manner as in the processes of FIGS. 2A to 2C of the first embodiment.

In the process of FIG. 8F, the phosphor plate 20 is polished, a buffer layer 21 is formed on the polished surface, the surface of the buffer layer 21 is polished, and ultraviolet light (excimer light) and plasma treatments are performed. These treatments are performed in the same manner as in the processes of FIGS. 2D to 2G of the first embodiment.

In the process of FIG. 8G, the phosphor plate 20 is mounted on the semiconductor light emitting layers 12 so that the buffer layer 21 is in contact with the semiconductor light emitting layers 12, and applying heat and applying pressure, and thereby the phosphor plate 20 is surface-activated bonded to the semiconductor light emitting layers 12. This process is performed in the same manner as the process of FIG. 3A in the first embodiment.

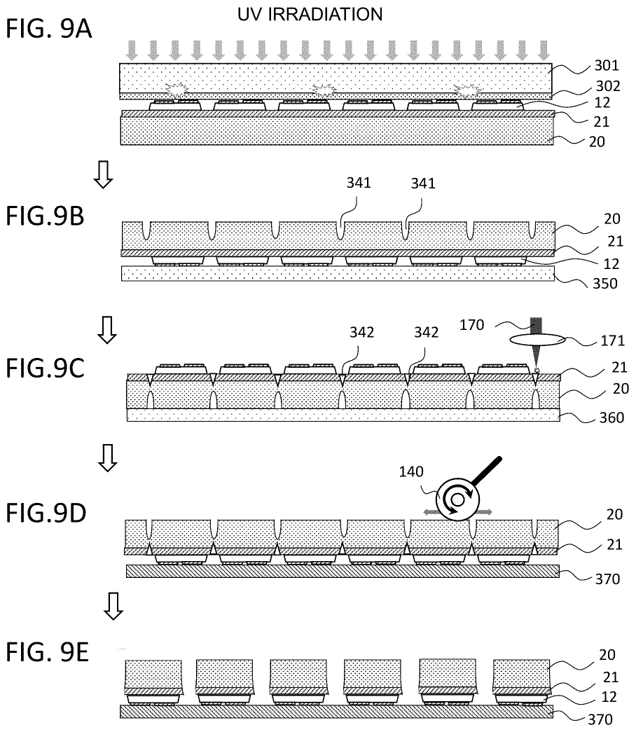

Next, in the process of FIG. 9A, the support substrate 301 and the adhesive layer 302 are removed from the semiconductor light emitting layers 12 by performing irradiation with ultraviolet light to generate bubbles.

It is noted that a substrate other than a translucent substrate can also be used as the support substrate 301. For example, when a substrate of Si or the like is used as the support substrate 301 and the semiconductor light emitting layers 12 are adhered by the adhesive layer 302 made of a metal material, a sacrificial layer made of silver is formed as an intermediate layer of the adhesive layer 302, and the sacrificial layer is dissolved with nitric acid or the like, so that the support substrate 301 and the adhesive layer 302 can be removed.

In the process of FIG. 9B, an adhesive sheet 350 is adhered to the electrode 13 side of the semiconductor light emitting layers 12, and incisions 341 are formed in the phosphor plate 20. This process is performed in the same manner as the process of FIG. 3B in the first embodiment, but differs from the first embodiment in that the depth of the incision 341 is formed so as not to reach the buffer layer 21.

In the process of FIG. 9C, the adhesive sheet 350 is removed, and an adhesive sheet 360 is adhered to the phosphor plate 20. A laser scribing device focuses laser light 170 with a lens 171 on the buffer layer 21 in the gap between the plurality of semiconductor light emitting layers 12 from the side where the semiconductor light emitting layers 12 are arranged, to form groove-shaped notches 342. This process is performed in the same manner as the process of FIG. 3C of the first embodiment, but differs from the first embodiment in that the notches 342 are formed directly in the buffer layer 21.

After that, the adhesive sheet 360 is removed, and an adhesive sheet 370 is adhered to the electrode 13 side of the semiconductor light emitting layers 12, and the processes of FIGS. 9D to 9E are performed in the same manner as the processes of FIGS. 3D and 3E of the first embodiment to individualize the individual semiconductor light emitting devices.

In this way, in the second embodiment, even in the light emitting element 10 from which the element substrate 11 has been removed, the phosphor plate 20 can be bonded by the surface-activated bonding.

In the second embodiment, since the notches 342 are provided in the buffer layer 21, it is possible to prevent stress from being applied to the light emitting element 10.

Other effects of the second embodiment are similar to those of the first embodiment.

In the second embodiment, in the process of FIG. 9C, the notches 342 are formed in the buffer layer 21 in the gaps between the plurality of semiconductor light emitting layers 12 from the side where the semiconductor light emitting layers 12 are arranged, but the notches 342 may be formed at the tips of incisions 341.

In the second embodiment, the notches 342 are formed, but since the buffer layer 21 is a thin film, the notch forming can be done arbitrarily as necessary. In other words, the notches 342 may not be provided.

The technology of the semiconductor light emitting device of this embodiment can be used in a lamp light source unit or a white light source module.

What is claimed is:

1. A method for manufacturing a semiconductor light emitting device in which a phosphor plate absorbing light emitted from a semiconductor light emitting layer and emitting fluorescence is bonded to a light emitting element including the semiconductor light emitting layer, the method comprising:
a light emitting element polishing process of polishing an upper surface of a light emitting element plate including a plurality of semiconductor light emitting layers arranged with gaps opened in a main plane direction;
a phosphor polishing process of polishing a lower surface of the phosphor plate;
a stacking process of mounting the phosphor plate on the light emitting element so that the upper surface of the light emitting element plate and the lower surface of the phosphor plate face each other, and applying heat and applying pressure to form a stacked body in which the phosphor plate is bonded to the light emitting element plate;
an incision forming process of forming incisions with a predetermined depth from the phosphor plate side of the stacked body at positions corresponding to the gaps between the plurality of semiconductor light emitting layers;
a notch forming process of forming notches in the gaps between the plurality of semiconductor light emitting layers from the light emitting element side of the stacked body; and
an individualizing process of dividing the stacked body between a tip of the incision and a tip of the notch to individualize the semiconductor light emitting device,
wherein a sum of the depth of the incision and a depth of the notch is shallower than a thickness of the stacked body, and
wherein one of the incision and the notch is formed with a depth extending beyond a bonding surface between the phosphor plate and the light emitting element plate.

2. The method for manufacturing a semiconductor light emitting device according to claim 1, further comprising, before the stacking process, a film forming process of forming a buffer layer made of an inorganic material on at least one of the upper surface of the light emitting element plate and the lower surface of the phosphor plate,
wherein the stacking process forms the stacked body by mounting the phosphor plate on the light emitting element so that the upper surface of the light emitting element plate and the lower surface of the phosphor plate are face each other via the buffer layer, and applies heat and applies pressure so that the phosphor plate is bonded onto the light emitting element plate via the buffer layer, and
wherein one of the incision and the notch is formed with a depth extending beyond the buffer layer of the bonding surface between the phosphor plate and the light emitting element plate.

3. The method for manufacturing a semiconductor light emitting device according to claim 1,
wherein the light emitting element includes an element substrate, and the light emitting element plate has a structure in which the plurality of semiconductor light emitting layers are fixed to a lower surface of the element substrate as a common element substrate with the gaps opened,
wherein the light emitting element polishing process is a process of polishing an upper surface of the common element substrate of the light emitting element plate, and
wherein the stacking process is a process of forming the stacked body by bonding the upper surface of the element substrate and the lower surface of the phosphor plate.

4. The method for manufacturing a semiconductor light emitting device according to claim 3, further comprising a film forming process of forming a buffer layer on at least one of the upper surface of the semiconductor light emitting layer and the lower surface of the phosphor plate before the stacking process,
wherein the stacking process forms the stacked body by bonding the upper surface of the semiconductor light emitting layer and the lower surface of the phosphor plate via the buffer layer, and
wherein the notch forming process is a process of forming the notches with a depth extending beyond the buffer layer.

5. The method for manufacturing a semiconductor light emitting device according to claim 4,
wherein in the film forming process, the buffer layer is formed on the lower surface of the phosphor plate.

6. The method for manufacturing a semiconductor light emitting device according to claim 1,
wherein the incision forming process forms the incisions by blade dicing, and
wherein the notch forming process forms the notches by laser scribing.

7. The method for manufacturing a semiconductor light emitting device according to claim 3,
wherein the element substrate is made of sapphire, and
wherein the phosphor plate is made of aluminum oxide containing phosphor particles.

8. The method for manufacturing a semiconductor light emitting device according to claim 2, wherein the buffer layer is made of amorphous aluminum oxide.
